(19) United States
(12) Patent Application Publication
(10) Pub. No.: US 2026/0110758 A1
(43) Pub. Date: Apr. 23, 2026

(54) MAGNETIC SENSOR

(71) Applicant: TDK Corporation, Tokyo (JP)

(72) Inventors: Hidekazu KOJIMA, Tokyo (JP); Hirokazu TAKAHASHI, Tokyo (JP)

(73) Assignee: TDK Corporation, Tokyo (JP)

(21) Appl. No.: 19/352,951

(22) Filed: Oct. 8, 2025

(30) Foreign Application Priority Data
Oct. 18, 2024 (JP) 2024-182451

(51) Int. Cl. G01R 33/09; H10N 50/10

(52) U.S. Cl. CPC G01R 33/093; H10N 50/10

(57) ABSTRACT

A magnetic sensor includes: an MR element including a magnetization pinned layer, a free layer, and a gap layer; a protective layer disposed above the MR element; and a conductive layer electrically connected to the MR element. The protective layer includes a first part and a second part, such that the second part is disposed so as to sandwich the first part between the second part and the MR element. When viewed in a stacking direction of the magnetization pinned layer, the gap layer, and the free layer, an outer edge of the second part is located on an inner side of the outer edge of the first part. The conductive layer comes in contact with the second part.

### CROSS REFERENCE TO RELATED APPLICATIONS

This application claims the benefit of Japanese Priority Patent Application No. 2024-182451 filed on Oct. 18, 2024, the entire contents of which are incorporated herein by reference.

### BACKGROUND

The disclosure relates to a magnetic sensor including a magnetoresistive element and a protective layer disposed above the magnetoresistive element.

In recent years, magnetic sensors have been used for a variety of applications. Examples of known magnetic sensors include one that uses a spin-valve magnetoresistive element provided on a substrate. The spin-valve magnetoresistive element includes a magnetization pinned layer, a direction of magnetization of which is fixed, a free layer, a direction of magnetization of which is variable depending on the direction of a target magnetic field, and a gap layer disposed between the magnetization pinned layer and the free layer.

US 2023/0324477 A1 discloses a magnetic sensor device including a plurality of tunnel magnetoresistance (TMR) elements. Each TMR element has a free layer having a disk-like structure. In the free layer, a magnetization pattern with closed flux, which is also called a vortex state, is spontaneously formed. In a magnetoresistive element including the free layer having the magnetic vortex structure as described in US 2023/0324477 A1, the center of the magnetic vortex structure moves according to a magnetic field to be detected, and this thus changes resistance of the magnetoresistive element.

In the TMR element, a lower electrode and an upper electrode are respectively connected to a bottom surface and a top surface of the TMR element in order to cause a sense current for magnetic signal detection to flow in a direction substantially perpendicular to a surface of each layer constituting the TMR element. The upper electrode is formed as follows, for example. First, an insulating layer is formed to cover the TMR element. Next, an opening exposing the top surface of the TMR element is formed in the insulating layer. Next, a conductive layer constituting at least a part of the upper electrode is formed to fill the opening.

After the opening is formed in the insulating layer, ion beam etching or reverse sputtering may be performed on a part of the top surface of the TMR element. In this case, depending on a condition of ion beam etching and a condition of reverse sputtering, the free layer of the TMR element may be damaged. The influence of the damage is notably apparent in the free layer having the magnetic vortex structure as described in US 2023/0324477 A1, in particular.

### SUMMARY

A magnetic sensor according to one embodiment of the disclosure includes: a magnetoresistive element including a magnetization pinned layer having magnetization with a fixed direction, a free layer having magnetization variable according to a magnetic field to be applied, and a gap layer disposed between the magnetization pinned layer and the free layer; a protective layer disposed above the magnetoresistive element; and a conductive layer electrically connected to the magnetoresistive element. The protective layer includes a first part and a second part, such that the second part is disposed so as to sandwich the first part between the second part and the magnetoresistive element. When viewed in a stacking direction of the magnetization pinned layer, the gap layer, and the free layer, an outer edge of the second part is located on an inner side of the outer edge of the first part. The conductive layer comes in contact with the second part.

Objects, features, and advantages of the disclosure will appear more fully from the following description.

### BRIEF DESCRIPTION OF THE DRAWINGS

The accompanying drawings are included to provide a further understanding of the disclosure and are incorporated in and constitute a part of this specification. The drawings illustrate example embodiments and, together with the specification, serve to explain the principles of the technology.

FIG. 1 is a plan view showing a magnetic sensor according to a first example embodiment of the disclosure.

FIG. 2 is a circuit diagram showing a circuit configuration of the magnetic sensor according to the first example embodiment of the disclosure.

FIG. 3 is a plan view showing a part of the magnetic sensor according to the first example embodiment of the disclosure.

FIG. 4 is a cross-sectional view showing a part of the magnetic sensor according to the first example embodiment of the disclosure.

FIG. 5 is an enlarged cross-sectional view showing a part of the magnetic sensor shown in FIG. 4.

FIG. 6 is a plan view showing a protective layer in the first example embodiment of the disclosure.

FIG. 7 is a perspective view showing a magnetoresistive element in the first example embodiment of the disclosure.

FIG. 8 is a plan view showing a free layer of the magnetoresistive element in the first example embodiment of the disclosure.

FIG. 9 is a plan view showing the free layer when a target magnetic field is applied to the magnetoresistive element in the first example embodiment of the disclosure.

FIG. 10 is a plan view showing the free layer when a target magnetic field is applied to the magnetoresistive element in the first example embodiment of the disclosure.

FIG. 11 is a cross-sectional view showing a step of a manufacturing method for the magnetic sensor according to the first example embodiment of the disclosure.

FIG. 12 is a cross-sectional view showing a step subsequent to the step shown in FIG. 11.

FIG. 13 is a cross-sectional view showing a step subsequent to the step shown in FIG. 12.

FIG. 14 is a cross-sectional view showing a step subsequent to the step shown in FIG. 13.

FIG. 15 is a cross-sectional view showing a step subsequent to the step shown in FIG. 14.

FIG. 16 is a cross-sectional view showing a part of the magnetic sensor of a modification example according to the first example embodiment of the disclosure.

FIG. 17 is a cross-sectional view showing a step of a manufacturing method for the magnetic sensor according to a second example embodiment of the disclosure.

FIG. 18 is a cross-sectional view showing a step subsequent to the step shown in FIG. 17.

FIG. 19 is a cross-sectional view showing a step subsequent to the step shown in FIG. 18.

FIG. 20 is an enlarged cross-sectional view showing a part of the magnetic sensor according to a third example embodiment of the disclosure.

FIG. 21 is an enlarged cross-sectional view showing a part of the magnetic sensor according to the fourth example embodiment of the disclosure.

### DETAILED DESCRIPTION

An object of the disclosure is to provide a magnetic sensor that is capable of reducing occurrence of a problem due to a conductive layer connected to a magnetoresistive element.

In the following, some example embodiments and modification examples of the disclosure will be described in detail with reference to the accompanying drawings. Note that the following description is directed to illustrative examples of the disclosure and not to be construed as limiting the technology. Factors including, without limitation, numerical values, shapes, materials, components, positions of the components, and how the components are coupled to each other are illustrative only and not to be construed as limiting the technology. Further, elements in the following example embodiments which are not recited in a most-generic independent claim of the disclosure are optional and may be provided on an as-needed basis. The drawings are schematic and are not intended to be drawn to scale. Like elements are denoted with the same reference numerals to avoid redundant descriptions.

### First Example Embodiment

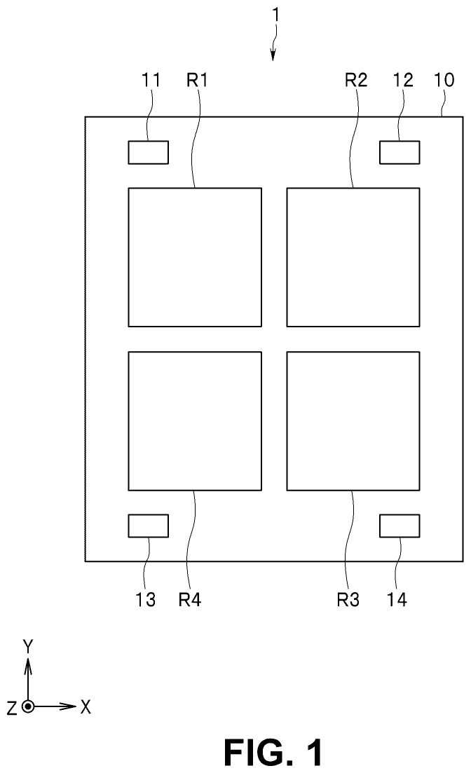

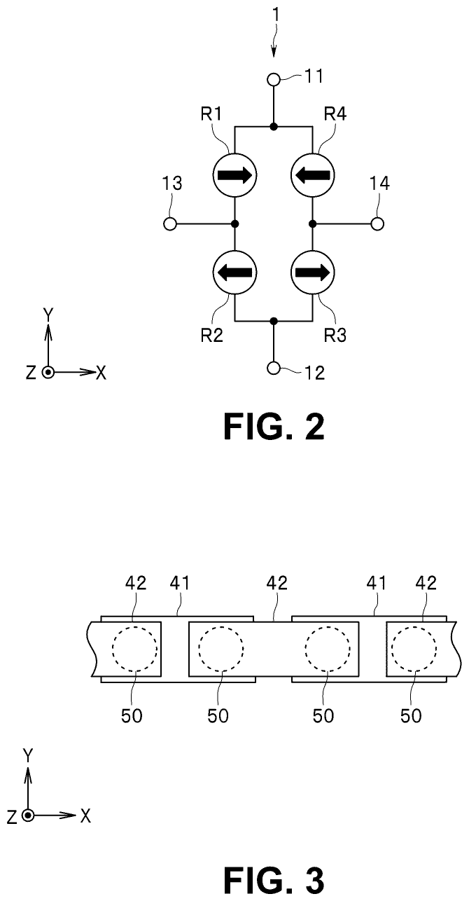

First, a schematic configuration of a magnetic sensor according to a first example embodiment of the disclosure will be described with reference to FIGS. 1 and 2. FIG. 1 is a plan view showing a magnetic sensor 1 according to the example embodiment. FIG. 2 is a circuit diagram showing a circuit configuration of the magnetic sensor 1 according to the example embodiment.

The magnetic sensor 1 according to the example embodiment includes a power supply terminal 11, a ground terminal 12, a first output terminal 13, a second output terminal 14, a first resistor section R1, a second resistor section R2, a third resistor section R3, a fourth resistor section R4, and a substrate 10. Each of the first to fourth resistor sections R1 to R4 includes a plurality of magnetoresistive elements (hereinafter referred to as MR elements). The first to fourth resistor sections R1 to R4, the power supply terminal 11, the ground terminal 12, and the first and second output terminals 13 and 14 are provided on the substrate 10.

As shown in FIG. 2, the first resistor section R1 is provided between the power supply terminal 11 and the first output terminal 13 in the circuit configuration. The second resistor section R2 is provided between the ground terminal 12 and the first output terminal 13 in the circuit configuration. The third resistor section R3 is provided between the ground terminal 12 and the second output terminal 14 in the circuit configuration. The fourth resistor section R4 is provided between the power supply terminal 11 and the second output terminal 14 in the circuit configuration. Note that, in the application, the expression “in the (a) circuit configuration” is used to indicate a layout in a circuit diagram, not a layout in a physical configuration.

A voltage or a current having specific magnitude is applied to the power supply terminal 11. The ground terminal 12 is connected to the ground.

Here, as shown in FIG. 1, an X direction, a Y direction, and a Z direction are defined. The X direction, the Y direction, and the Z direction are orthogonal to one another. The opposite directions to the X, Y, and Z directions will be expressed as −X, −Y, and −Z directions, respectively. In the example embodiment, in particular, a direction perpendicular to the surface of the substrate 10 is referred to as the Z direction.

As used herein, the term “above” refers to positions located forward of a certain reference position in the Z direction, and “below” refers to positions opposite from the “above” positions with respect to the certain reference position. For components of the magnetic sensor 1, the term “top surface” refers to a surface of the component lying at the end thereof in the Z direction, and “bottom surface” refers to a surface of the component lying at the end thereof in the −Z direction. The expression “when viewed in a specific direction (e.g., the Z direction)” means that an object is viewed from a position away in the specific direction or in one direction parallel to the specific direction.

FIG. 1 shows an example of the layout of the first to fourth resistor sections R1 to R4. In this example, the first and second resistor sections R1 and R2 are arranged in a direction parallel to the X direction. The second resistor section R2 is disposed forward of the first resistor section R1 in the X direction.

The third and fourth resistor sections R3 and R4 are arranged in a direction parallel to the X direction. The fourth resistor section R4 is disposed forward of the third resistor section R3 in the −X direction. The third resistor section R3 is disposed forward of the second resistor section R2 in the −Y direction. The fourth resistor section R4 is disposed forward of the first resistor section R1 in the −Y direction.

Note that the layout of the first to fourth resistor sections R1 to R4 is not limited to the example shown in FIG. 1. For example, the first to fourth resistor sections R1 to R4 may be disposed in a specific order in the direction parallel to the X direction or in a direction parallel to the Y direction.

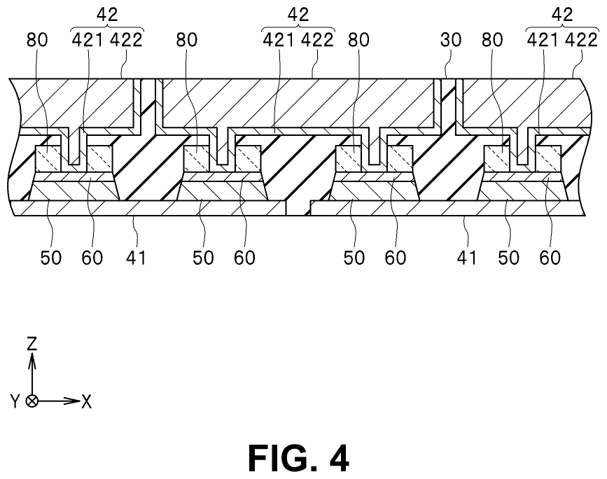

Next, a specific structure of the magnetic sensor 1 will be described in detail with reference to FIGS. 3 and 4. FIG. 3 is a plan view showing a part of the magnetic sensor 1. FIG. 4 is a cross-sectional view showing a part of the magnetic sensor 1.

The magnetic sensor 1 in the example embodiment includes a plurality of MR elements 50 and a plurality of lower electrodes 41 and a plurality of upper electrodes 42 for electrically connecting the plurality of MR elements 50. The plurality of lower electrodes 41 are disposed above the substrate 10 (see FIG. 1). The plurality of MR elements 50 are disposed above the plurality of lower electrodes 41. The plurality of upper electrodes 42 are disposed above the plurality of MR elements 50.

A method of connecting the plurality of MR elements 50 and the plurality of lower electrodes 41 and the plurality of upper electrodes 42 is as follows. As shown in FIG. 3, each individual lower electrode 41 has an elongated shape. A gap is formed between two lower electrodes 41 adjacent in a longitudinal direction of the lower electrodes 41. On the top surface of the lower electrode 41, the MR elements 50 are respectively disposed near both ends in the longitudinal direction. Each individual upper electrode 42 has an elongated shape, and is disposed above two lower electrodes 41 adjacent in the longitudinal direction of the lower electrodes 41 and electrically connects the two adjacent MR elements 50 to each other. In such a manner, the plurality of MR elements 50 are connected in series.

The upper electrode 42 may include an underlayer 421 and a conductive layer 422 disposed above the underlayer 421. The underlayer 421 comes in contact with the top surfaces of the MR elements 50. As a material of the underlayer 421, for example, Ta, Ti, or the like is used. As a material of the conductive layer 422, for example, Cu, Au, Al, or the like is used.

The magnetic sensor 1 may further include a protective layer 70 disposed above the MR element 50, an inorganic material layer 80 disposed above the protective layer 70, and an insulating layer 30. The insulating layer 30 is disposed around the lower electrode 41, around the MR element 50, around the protective layer 70, around the inorganic material layer 80, and around the upper electrode 42. The insulating layer 30 may be a single-layer film, or may be a multi-layer film. In the latter case, the multi-layer film may be formed of one insulating material, or may be formed of a plurality of insulating materials.

As a material of the inorganic material layer 80, for example, carbon, Al₂O₃, or the like is used. As a material of the insulating layer 30, for example, SiO₂, Al₂O₃, or the like is used.

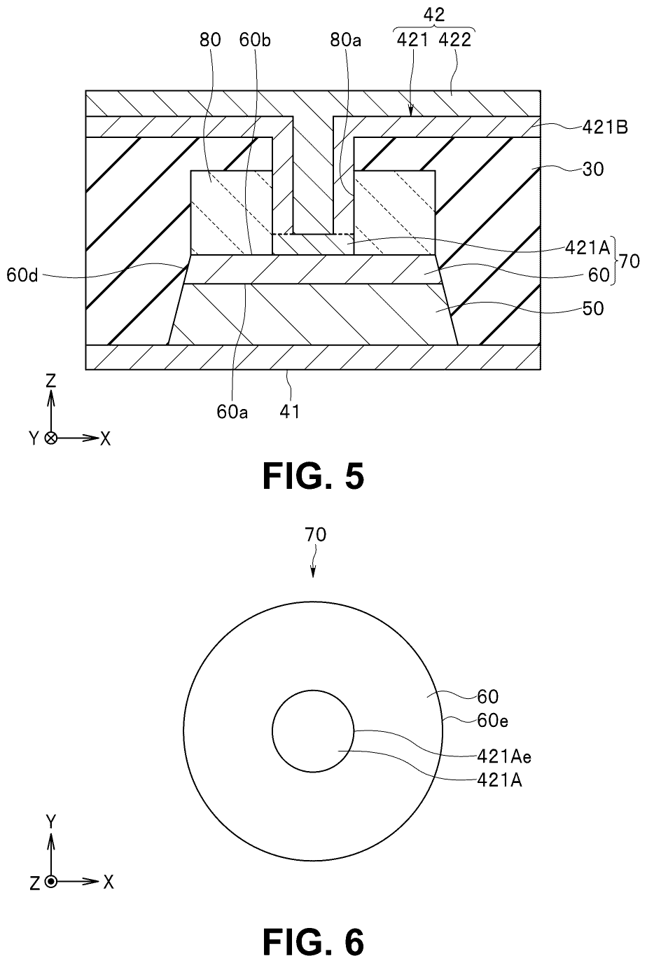

Next, with reference to FIGS. 5 and 6, structures of the protective layer 70 and the inorganic material layer 80 will be described in detail. FIG. 5 is an enlarged cross-sectional view showing a part of the magnetic sensor 1 shown in FIG. 4. FIG. 6 is a plan view showing the protective layer 70 in the example embodiment. The protective layer 70 includes a first part 60 disposed above the MR element 50 and a second part 421A interposing the first part 60 between the second part 421A and the MR element 50.

In the example embodiment, in particular, the second part 421A may be a part of the underlayer 421. In other words, the underlayer 421 may include the second part 421A and a part 421B other than the second part 421A. In FIG. 5, a boundary between the second part 421A and the part 421B is shown by a broken line. Note that, also in the drawings to be used in the description below, which are similar to FIG. 5, the boundary between the second part 421A and the part 421B is shown by a broken line.

The first part 60 may include a first metal film formed of a first metal material. The first part 60 may be a single-layer film including the first metal film, or may be a multi-layer film including the first metal film. The second part 421A may include a second metal film formed of the first metal material. The second part 421A may be a single-layer film including the second metal film, or may be a multi-layer film including the second metal film. When at least one of the first part 60 and the second part 421A is a multi-layer film including the first metal film, the protective layer 70 may further include a third metal film formed of a second metal material. The third metal film may be disposed between the first metal film and the second metal film.

The first metal material may be Ta, for example. When the first part 60 is a multi-layer film, the first part 60 may include at least one metal film formed of a metal material of Ru, Ta, Cu, or Cr or an Ni-based non-magnetic alloy such as NiCr, for example, as the third metal film, in addition to the first metal film formed of Ta. When the second part 421A is a multi-layer film, the second part 421A may include at least one metal film formed of a metal material, such as Ti, for example, as the third metal film, in addition to the second metal film formed of Ta. In one example, the first part 60 is a multi-layer film in which a metal film formed of Ru and a metal film formed of Ta are stacked, and the second part 421A is a multi-layer film in which a metal film formed of Ti and a metal film formed of Ta are stacked.

As shown in FIG. 5, the first part 60 of the protective layer 70 includes a first surface 60a and a second surface 60b lying at both ends in a direction parallel to the Z direction. The first surface 60a faces the MR element 50. The second surface 60b faces the second part 421A. The second surface 60b may be entirely parallel to the first surface 60a, or may be partially parallel to the first surface 60a.

As shown in FIG. 6, the planar shape (shape viewed in the Z direction) of the second part 421A is smaller than the planar shape of the first part 60. In FIG. 6, a reference sign 60e denotes an outer edge of the first part 60 when viewed in the Z direction, and a reference sign 421Ae denotes an outer edge of the second part 421A when viewed in the Z direction. When viewed in the Z direction, the outer edge 421Ae of the second part 421A is located on the inner side of the outer edge 60e of the first part 60.

Note that the outer edge 60e shown in FIG. 6 may be an outer edge of the second surface 60b of the first part 60. In other words, when viewed in the Z direction, the outer edge 421Ae of the second part 421A may be located on the inner side of the outer edge of the second surface 60b of the first part 60.

FIG. 6 shows an example of a case in which the planar shape of the first part 60 and the planar shape of the second part 421A each have a circular shape. In this case, when viewed in the Z direction, the second part 421A is preferably disposed to overlap the center of the planar shape of the first part 60, and is more preferably disposed so that center of the planar shape of the first part 60 and the center of the planar shape of the second part 421A overlap.

The first part 60 further includes a side surface 60d connecting the first surface 60a and the second surface 60b. At least a part of the side surface 60d may be inclined relative to a direction (stacking direction) parallel to the Z direction. The cross-sectional area of the first part 60 parallel to the XY plane may decrease as it is closer to the second surface 60b. When viewed in the Z direction, the outer edge of the second surface 60b may be located on the inner side of the outer edge of the first surface 60a.

The inorganic material layer 80 is disposed around the second part 421A on the first part 60 of the protective layer 70. When viewed in the Z direction, the outer edge of the planar shape of the inorganic material layer 80 may match the outer edge 60e of the first part 60 or the outer edge of the second surface 60b.

Note that the outer diameter of the planar shape of the inorganic material layer 80 may be equal to or less than the outer diameter of the planar shape of the MR element 50. The cross-sectional area of the inorganic material layer 80 parallel to the XY plane may be constant regardless of the distance from the second surface 60b, or may decrease as it is more distant from the second surface 60b. In the latter case, the inorganic material layer 80 may include a side surface connecting the bottom surface and the top surface of the inorganic material layer 80, which is a side surface inclined relative to the direction (stacking direction) parallel to the Z direction. In this case, the outer edge of the top surface of the inorganic material layer 80 is located on the inner side of the outer edge of the planar shape of the MR element 50 when viewed in the Z direction.

The inorganic material layer 80 includes an opening 80a exposing a part of the second surface 60b of the first part 60 of the protective layer 70. The size of the opening 80a in cross-section of the inorganic material layer 80 parallel to the XY plane may be constant regardless of the distance from the second surface 60b, or may increase as it is more distant from the second surface 60b.

The insulating layer 30 may cover the top surface of the inorganic material layer 80. In this case, the insulating layer 30 may include an opening exposing the opening 80a of the inorganic material layer 80.

The underlayer 421 including the second part 421A is disposed along a wall surface of the opening 80a of the inorganic material layer 80 and a part of the second surface 60b. When the insulating layer 30 covers the top surface of the inorganic material layer 80, the underlayer 421 is disposed further along a surface of the insulating layer 30 including a wall surface of the opening of the insulating layer 30.

The second part 421A directly comes in contact with the first part 60, and comes in contact with the wall surface of the opening 80a of the inorganic material layer 80. Because the second part 421A is a component of the upper electrode 42, it can also be said that the upper electrode 42 comes in contact with the first part 60. Note that the part 421B of the underlayer 421 comes in contact with the wall surface of the opening 80a of the inorganic material layer 80 but does not come in contact with the first part 60.

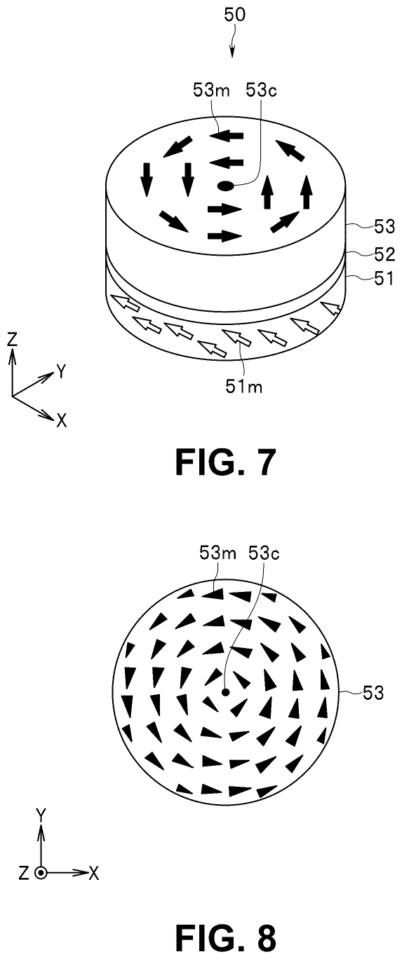

Next, a configuration of the MR element 50 will be described with reference to FIGS. 7 and 8. FIG. 7 is a perspective view showing the MR element 50. FIG. 8 is a plan view showing a free layer of the MR element 50.

The MR element 50 includes a magnetization pinned layer 51 having magnetization 51m with a fixed direction, a free layer 53, and a gap layer 52 disposed between the magnetization pinned layer 51 and the free layer 53. A material and a shape of the free layer 53 may be selected so that the free layer 53 can have a magnetic vortex structure (also referred to as a vortex structure). The gap layer 52 is a tunnel barrier layer or a non-magnetic conductive layer.

The free layer 53 has a cylindrical or a substantially cylindrical shape. The free layer 53 has magnetization 53m having a vortex pattern about a center 53c of the magnetic vortex structure. When there is no magnetic field applied to the MR element 50, the center 53c of the magnetic vortex structure matches or substantially matches the axis of the cylinder. The free layer 53 is configured so that the center 53c of the magnetic vortex structure can move according to a target magnetic field MF. Note that, in the examples shown in FIGS. 7 and 8, the overall MR element 50 has a cylindrical shape.

The center 53c of the magnetic vortex structure moves when a component of the target magnetic field MF, which is in a direction orthogonal to the Z direction, is applied to the free layer 53. The free layer 53 is preferably not saturated within a range of variation of strength of the component.

Here, a dimension in the direction parallel to the Z direction is referred to as thickness. The thickness of the first part 60 of the protective layer 70 may be set based on the thickness of the free layer 53. In the example embodiment, in particular, the thickness of the first part 60 may be within a range of 40 to 100% of the thickness of the free layer 53. Alternatively, the thickness of the first part 60 may be within a range of 20 to 40% of the thickness of the free layer 53.

In the example embodiment, the magnetization 51m of the magnetization pinned layer 51 includes a component in a direction parallel to the X direction. Note that, when the magnetization 51m of the magnetization pinned layer 51 includes a component in a specific direction, the component in the specific direction may be the main component of the magnetization 51m of the magnetization pinned layer 51. In the example embodiment, when the magnetization 51m of the magnetization pinned layer 51 includes the component in the specific direction, the direction of the magnetization 51m of the magnetization pinned layer 51 is the specific direction or substantially the specific direction.

The MR element 50 may further include an antiferromagnetic layer. The antiferromagnetic layer is formed of an antiferromagnetic material, and is in exchange coupling with the magnetization pinned layer 51 to thereby fix the direction of the magnetization 51m of the magnetization pinned layer 51. Alternatively, the magnetization pinned layer 51 may be a so-called self-pinned layer (Synthetic Ferri Pinned layer, SFP layer). The self-pinned layer has a stacked ferri structure in which a ferromagnetic layer, a nonmagnetic intermediate layer, and a ferromagnetic layer are stacked, and the two ferromagnetic layers are antiferromagnetically coupled.

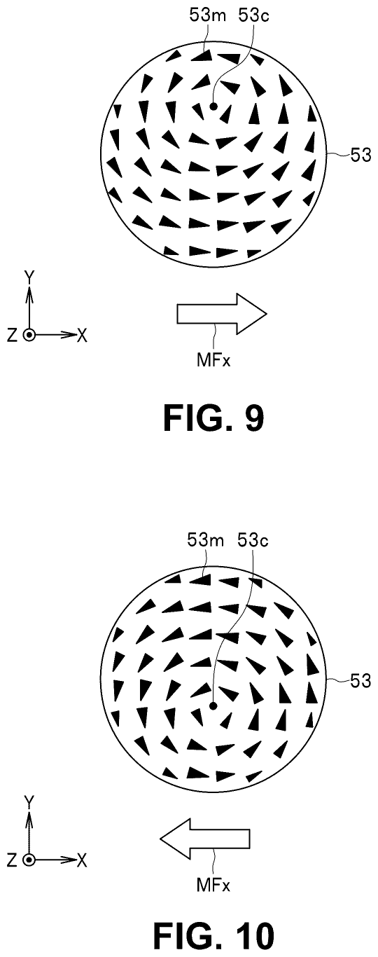

Here, resistance of the MR element 50 will be described by taking an example of a case in which the direction of the magnetization 51m of the magnetization pinned layer 51 is the −X direction. FIGS. 9 and 10 show the free layer 53 when a magnetic field component MFx of the target magnetic field MF, which is in a direction parallel to the X direction, is applied to the free layer 53.

FIG. 9 shows the free layer 53 when the direction of the magnetic field component MFx is the X direction. In this case, the center 53c of the magnetic vortex structure moves according to the magnetic field component MFx, and the amount of the magnetization 53m in the X direction is larger than the amount of the magnetization 53m in the −X direction. In this case, the resistance of the MR element 50 increases.

FIG. 10 shows the free layer 53 when the direction of the magnetic field component MFx is the −X direction. In this case, the center 53c of the magnetic vortex structure moves according to the magnetic field component MFx, and the amount of the magnetization 53m in the −X direction is larger than the amount of the magnetization 53m in the X direction. In this case, the resistance of the MR element 50 decreases.

The amount of change in the resistance of the MR element 50 depends on the strength of the magnetic field component MFx. When the direction of the magnetic field component MFx is the X direction, the amount of the magnetization 53m in the X direction increases as the strength of the magnetic field component MFx increases. The resistance of the MR element 50 increases as the amount of the magnetization 53m in the X direction increases. When the direction of the magnetic field component MFx is the −X direction, the amount of the magnetization 53m in the −X direction increases as the strength of the magnetic field component MFx increases. The resistance of the MR element 50 decreases as the amount of the magnetization 53m in the −X direction increases. As the strength of the magnetic field component MFx increases, the resistance of the MR element 50 changes so that the amount of increase or the amount of decrease increases. As the strength of the magnetic field component MFx decreases, the resistance of the MR element 50 changes so that the amount of increase or the amount of decrease decreases. In the example embodiment, in particular, the relationship between the strength of the magnetic field component MFx and the resistance of the MR element 50 is a linear or substantially linear relationship, on the condition that the requirement that the free layer 53 is not saturated is satisfied.

Next, with reference to FIG. 2, the direction of the magnetization 51m of the magnetization pinned layer 51 in each of the first to fourth resistor sections R1 to R4 will be described. The magnetization 51m of the magnetization pinned layer 51 of each of the plurality of MR elements 50 in the first resistor section R1 includes a component in a first magnetization direction. The magnetization 51m of the magnetization pinned layer 51 of each of the plurality of MR elements 50 in the second resistor section R2 includes a component in a second magnetization direction opposite the first magnetization direction. The magnetization 51m of the magnetization pinned layer 51 of each of the plurality of MR elements 50 in the third resistor section R3 includes a component in the first magnetization direction. The magnetization 51m of the magnetization pinned layer 51 of each of the plurality of MR elements 50 in the fourth resistor section R4 includes a component in the second magnetization direction. In FIG. 2, each of the two arrows in the first and third resistor sections R1 and R3 shows the first magnetization direction. In FIG. 2, each of the two arrows in the second and fourth resistor sections R2 and R4 shows the second magnetization direction. In the example embodiment, in particular, the first magnetization direction is the X direction, and the second magnetization direction is the −X direction.

Next, with reference to FIG. 2, at least one detection signal generated by the magnetic sensor 1 will be described. When the direction of the magnetic field component MFx is the X direction, the resistance of each of the plurality of MR elements 50 of the first and third resistor sections R1 and R3 decreases and the resistance of each of the plurality of MR elements 50 of the second and fourth resistor sections R2 and R4 increases, compared to the state where the magnetic field component MFx is not present. As a result, the resistance of each of the first and third resistor sections R1 and R3 decreases and the resistance of each of the second and fourth resistor sections R2 and R4 increases.

When the direction of the magnetic field component MFx is the −X direction, the change in the resistance of each of the first to fourth resistor sections R1 to R4 is opposite to that in the foregoing case where the direction of the magnetic field component MFx is the X direction.

As described above, changes in the direction and the strength of the magnetic field component MFx cause the resistances of the first to fourth resistor sections R1 to R4 to change such that the resistances of the first and third resistor sections R1 and R3 increase while the resistances of the second and fourth resistor sections R2 and R4 decrease, or such that the resistances of the first and third resistor sections R1 and R3 decrease while the resistances of the second and fourth resistor sections R2 and R4 increase. This changes the potential of a connection point of the first and second resistor sections R1 and R2, i.e., the potential of the first output terminal 13, and the potential of a connection point of the third and fourth resistor sections R3 and R4, i.e., the potential of the second output terminal 14. The magnetic sensor 1 may generate a signal corresponding to the potential of the first output terminal 13 and a signal corresponding to the potential of the second output terminal 14 as detection signals. Alternatively, the magnetic sensor 1 may generate a signal corresponding to a potential difference between the first output terminal 13 and the second output terminal 14 as a detection signal. In this case, the magnetic sensor 1 may further include a differential amplifier (difference detector) that outputs the signal corresponding to the potential difference between the first output terminal 13 and the second output terminal 14 as the detection signal.

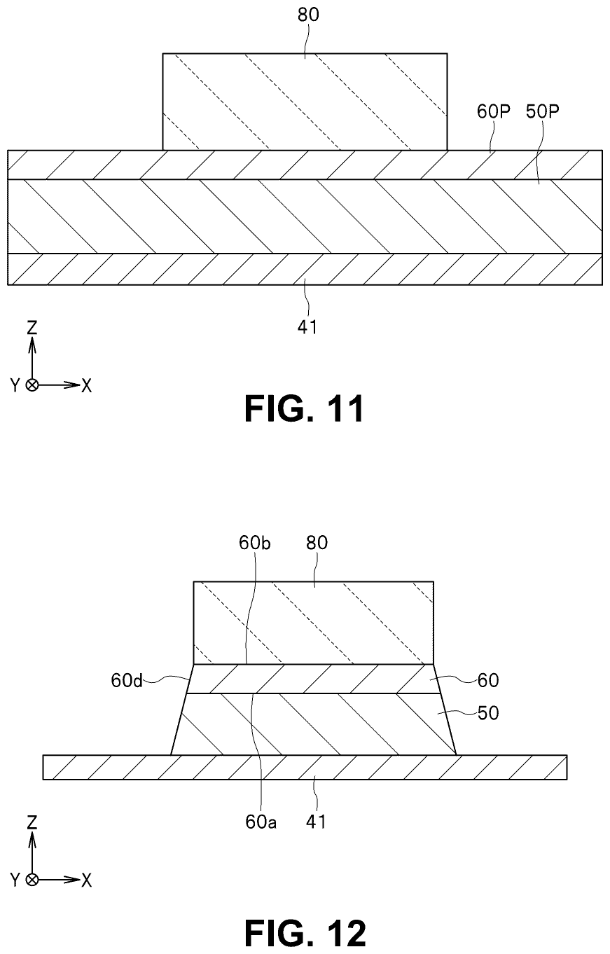

Next, with reference to FIGS. 11 to 15, a manufacturing method for the magnetic sensor 1 according to the example embodiment will be described. FIGS. 11 to 15 show cross-sections of a stacked body in a manufacturing process for the magnetic sensor 1. Here, the manufacturing method for the magnetic sensor 1 will be described, focusing on one MR element 50. In the manufacturing method for the magnetic sensor 1, first, an insulating layer (not shown) may be formed on the substrate 10 (see FIG. 1). FIG. 11 shows the next step. In this step, first, the lower electrode 41 is formed. Next, an initial MR element 50P to later become the MR element 50 is formed on the lower electrode 41. Note that, before forming the initial MR element 50P, a buffer layer (not shown) formed of a non-magnetic metal material may be formed on the lower electrode 41.

Next, an initial protective layer 60P to later become the first part 60 of the protective layer 70 is formed on the initial MR element 50P. Next, the inorganic material layer 80 is formed on the initial protective layer 60P. The inorganic material layer 80 has a shape corresponding to the planar shape of the MR element 50. Note that the manufacturing method for the magnetic sensor 1 according to the example embodiment will be described by taking an example of a case in which the inorganic material layer 80 is formed of carbon.

FIG. 12 shows the next step. In this step, with use of the inorganic material layer 80 as an etching mask, a part of each of the initial MR element 50P and the initial protective layer 60P is etched using ion beam etching, for example. When each of the initial MR element 50P and the initial protective layer 60P is etched, a re-deposited film may be formed on a surface of each of the initial MR element 50P and the initial protective layer 60P due to etched and scattered substances. When ion beam etching is used, the re-deposited film can be removed by inclining an ion beam progression direction relative to the stacking direction. A part of the initial protective layer 60P that remains after the etching becomes the first part 60 of the protective layer 70.

Here, a step of fixing the direction of magnetization of the magnetization pinned layer 51 will be described in detail. The initial MR element 50P shown in FIG. 11 includes at least an initial magnetization pinned layer to later become the magnetization pinned layer 51, the free layer 53, and the gap layer 52.

In the step of fixing the direction of magnetization of the magnetization pinned layer 51, the direction of magnetization of the initial magnetization pinned layer is fixed to the specific direction, using laser light and external magnetic fields in the specific direction after the initial MR element 50P is formed. For example, a plurality of initial MR elements 50P to later become the plurality of MR elements 50 of the first and third resistor sections R1 and R3 are irradiated with laser light while an external magnetic field in the first magnetization direction (X direction) is applied thereto. In the case where the initial MR elements 50P include the antiferromagnetic layers, the irradiation of the laser light is performed so that the temperature of the plurality of initial MR elements 50P irradiated with the laser light becomes equal to or higher than a blocking temperature of the antiferromagnetic layers. The temperature of the plurality of initial MR elements 50P can be adjusted, for example, by the intensity and the pulse width of the laser light. After the irradiation of the laser light, when the temperature of the plurality of initial MR elements 50P becomes lower than the blocking temperature, the direction of the magnetization of the initial magnetization pinned layer is fixed in the first magnetization direction. This transforms the initial magnetization pinned layer into the magnetization pinned layer 51.

In a plurality of other initial MR elements 50P to later become the plurality of MR elements 50 of the second and fourth resistor sections R2 and R4, by setting the direction of the external magnetic field to the second magnetization direction (−X direction), the direction of the magnetization of the initial magnetization pinned layer of each of the plurality of other initial MR elements 50P can be fixed in the second magnetization direction.

The step of fixing the direction of the magnetization of the initial magnetization pinned layer described above may be performed after the step of etching the initial MR element 50P shown in FIG. 12. In this case, when the direction of the magnetization of the initial magnetization pinned layer is fixed, the initial magnetization pinned layer becomes the magnetization pinned layer 51. Alternatively, the step of fixing the direction of the magnetization of the initial magnetization pinned layer described above may be performed before the step of etching the initial MR element 50P shown in FIG. 12. In this case, when the initial MR element 50P is etched, the initial magnetization pinned layer is also etched. This transforms the initial magnetization pinned layer into the magnetization pinned layer 51.

Note that, in FIG. 12, the side surface of the MR element 50 is inclined relative to the direction parallel to the Z direction. The side surface of the MR element 50 may include a plurality of parts whose respective angles formed relative to the direction parallel to the Z direction are different. Alternatively, at least a part of the side surface of the MR element 50 may be parallel to or substantially parallel to the Z direction.

In FIG. 12, the side surface 60d of the first part 60 of the protective layer 70 is inclined relative to the direction parallel to the Z direction. The angle formed by the side surface 60d of the first part 60 relative to the direction parallel to the Z direction may be the same as or different from the angle formed by the side surface of the MR element 50 relative to the direction parallel to the Z direction. The side surface 60d of the first part 60 may include a plurality of parts whose respective angles formed relative to the direction parallel to the Z direction are different. Alternatively, at least a part of the side surface 60d of the first part 60 may be parallel to or substantially parallel to the Z direction.

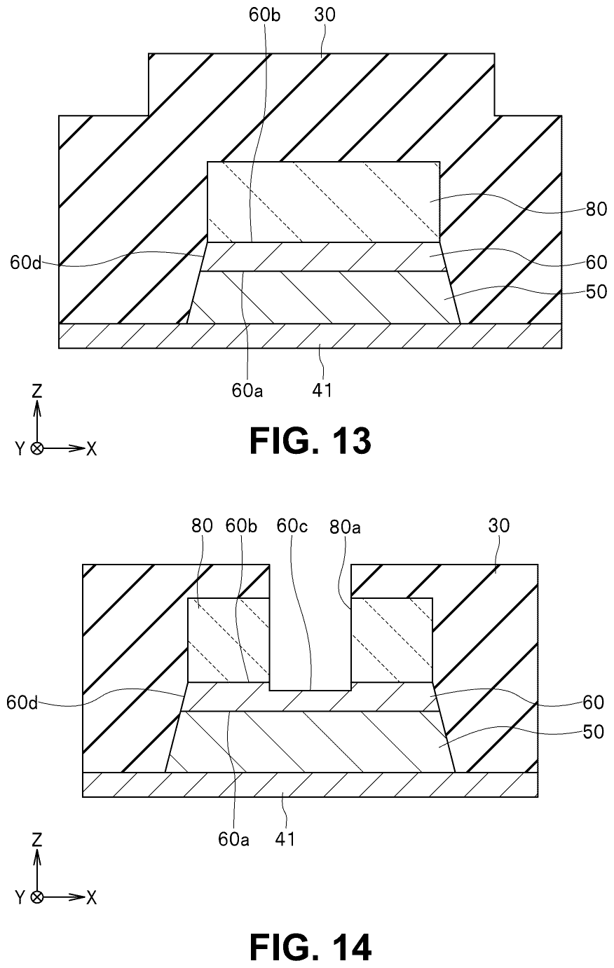

FIG. 13 shows the next step. In this step, the insulating layer 30 is formed to cover the lower electrode 41, the MR element 50, the first part 60, and the inorganic material layer 80. The insulating layer 30 is formed so that the top surface of the insulating layer 30 is disposed above the top surface of the inorganic material layer 80.

FIG. 14 shows the next step. In this step, a part of the insulating layer 30 is polished using chemical mechanical polishing (hereinafter referred to as CMP), for example. The insulating layer 30 may be polished to a position at which the top surface of the inorganic material layer 80 is not exposed, for example. Next, a photoresist mask (not shown) is formed on the insulating layer 30. The photoresist mask (not shown) includes an opening having a shape corresponding to the opening 80a of the inorganic material layer 80 to be formed later. Next, with use of the photoresist mask (not shown), a part of the insulating layer 30 is selectively etched using reactive ion etching (hereinafter referred to as RIE), for example. The insulating layer 30 is etched until the top surface of the inorganic material layer 80 is exposed.

Next, at least a part of the inorganic material layer 80 is selectively etched. In the example embodiment, in particular, a part of the inorganic material layer 80 is etched so that the opening 80a is formed in the inorganic material layer 80. When the inorganic material layer 80 is formed of carbon, the inorganic material layer 80 is etched using RIE with use of an etching gas containing O₂. The inorganic material layer 80 is etched until the second surface 60b of the first part 60 of the protective layer 70 is exposed.

Note that, in the step of etching the inorganic material layer 80, a part of the first part 60 may be etched together with the inorganic material layer 80. When the first part 60 is etched, a recess 60c, which is recessed from the second surface 60b toward the first surface 60a and has such a depth as to not reach the first surface 60a, may be formed in the first part 60. In the example shown in FIG. 14, the first part 60 includes the recess 60c. In the example embodiment, in particular, the outer diameter of the planar shape of the recess 60c may be smaller than the outer diameter of the inorganic material layer 80. The area of a contact surface between the upper electrode 42 to be formed later and the first part 60 of the protective layer 70 may be equal to the area of the planar shape of the recess 60c.

When the inorganic material layer 80 is etched using RIE with use of an etching gas containing O₂ as described above, an oxide film is formed on the second surface 60b of the first part 60. Thus, in this case, the oxide film is preferably removed using ion beam etching or reverse sputtering, for example, after the inorganic material layer 80 is etched.

A part of the second surface 60b other than the recess 60c is covered by the inorganic material layer 80. Thus, a state of the surface of the recess 60c and a state of the surface of the part other than the recess 60c are different from each other. For example, surface roughness of the surface of the recess 60c and surface roughness of the surface of the part other than the recess 60c may be different from each other. Note that any indicator may be used as the indicator of the surface roughness.

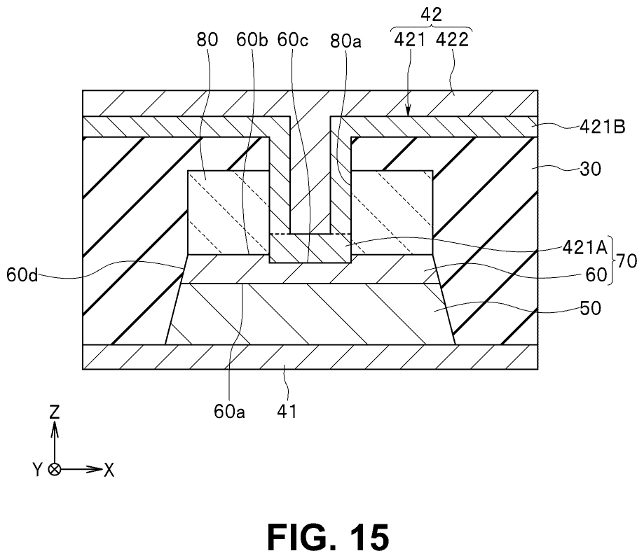

FIG. 15 shows the next step. In this step, first, the underlayer 421 is formed along the second surface 60b of the first part 60 or the surface of the recess 60c, the wall surface of the opening 80a of the inorganic material layer 80, and the surface of the insulating layer 30. When the first part 60 includes the recess 60c, at least a part of the second part 421A of the underlayer 421 is provided within the recess 60c. The underlayer 421 is formed using electroless plating or sputtering, for example.

Next, the conductive layer 422 is formed on the underlayer 421. The conductive layer 422 is formed using electroplating, for example. The underlayer 421 serves as a base for the conductive layer 422, and is used as an electrode and a seed layer when the conductive layer 422 is formed using electroplating. Next, the underlayer 421 and the conductive layer 422 are polished using CMP, for example, until the insulating layer 30 is exposed. This completes the upper electrode 42.

Note that the conductive layer 422 may be formed to completely fill the opening 80a of the inorganic material layer 80, or may be formed not to completely fill the opening 80a. In the latter case, a void may be formed in the conductive layer 422.

The above has described the manufacturing method for the magnetic sensor 1, focusing on one MR element 50. In the manufacturing method for the magnetic sensor 1, the plurality of MR elements 50, the plurality of lower electrodes 41, and the plurality of upper electrodes 42 are formed. After the plurality of upper electrodes 42 are formed, formation of a plurality of terminals corresponding to the power supply terminal 11, the ground terminal 12, and the first and second output terminals 13 and 14 and wiring for connecting the plurality of terminals and the plurality of MR elements 50 and the like are performed, and this thus completes the magnetic sensor 1.

The operation and effect of the magnetic sensor 1 according to the example embodiment will now be described. In the example embodiment, in order to form the conductive layer 422 constituting a part of the upper electrode 42, the opening 80a needs to be formed in the inorganic material layer 80. As described above, when the opening 80a of the inorganic material layer 80 is formed, the second surface 60b of the first part 60 of the protective layer 70 is exposed. If the protective layer 70 is not provided, the top surface of the MR element 50 is exposed in etching the inorganic material layer 80. Depending on a condition of etching the inorganic material layer 80, the top surface of the MR element 50 needs to be etched using ion beam etching or reverse sputtering, for example, after the inorganic material layer 80 is etched. Depending on a condition of ion beam etching and a condition of reverse sputtering, the free layer 53 of the MR element 50 may be damaged. In the example embodiment, in particular, when the free layer 53 is damaged, the magnetic vortex structure cannot be formed accurately, and as a result, hysteresis characteristics of the MR element 50 may deteriorate.

To address these, in the example embodiment, the protective layer 70 is provided on the MR element 50. Consequently, according to the example embodiment, occurrence of a problem due to formation of the conductive layer 422 can be reduced.

The conductive layer 422 has relatively large volume. If the conductive layer 422 directly comes in contact with the MR element 50, the free layer 53 may be damaged due to a difference in characteristics between the conductive layer 422 and other components. To address these, in the example embodiment, the conductive layer 422 does not come in contact with the MR element 50. In the example embodiment, in particular, the protective layer 70 includes the first part 60 and the second part 421A. The conductive layer 422 comes in contact with the second part 421A. Consequently, according to the example embodiment, the conductive layer 422 can be placed farther from the MR element 50, compared to a case in which the second part 421A is not provided. As a result, according to the example embodiment, occurrence of a problem due to the conductive layer 422 can be reduced.

Incidentally, as a method of forming the MR element 50 and the upper electrode 42, a method of formation using a photoresist mask without the use of the inorganic material layer 80 is considered. The method of formation using a photoresist mask is hereinafter referred to as a formation method of a comparative example. In the formation method of the comparative example, first, a photoresist mask is formed on the initial MR element 50P. The photoresist mask has a shape corresponding to the planar shape of the MR element 50.

As the photoresist mask, a photoresist mask including a lower layer and an upper layer disposed on the lower layer is used. The upper layer is formed of a photoresist that is patterned using photolithography. The lower layer is formed of a material that is dissolved by a developer used in patterning the upper layer, for example. Such a photoresist mask has an undercut forming a space between the photoresist mask and its base layer.

In the formation method of the comparative example, next, the initial MR element 50P is etched using ion beam etching with use of the photoresist mask. This transforms the initial MR element 50P into the MR element 50. Next, with the photoresist mask remaining, the insulating layer 30 is formed on the entire top surface of the stacked body. Next, the photoresist mask is removed. Next, the upper electrode 42 is formed on the MR element 50 and the insulating layer 30.

In order to form the magnetic vortex structure in the free layer 53, the thickness of the free layer 53 needs to be increased. When the initial MR element 50P including the free layer 53 having a large thickness is etched, a re-deposited film formed due to substances scattered in etching increases, and thus the width of the lower layer of the photoresist mask needs to be reduced. In that case, however, the photoresist mask may collapse during etching. When the insulating layer 30 is formed with the collapsing photoresist mask, the insulating layer 30 formed around the MR element 50 and the insulating layer 30 formed on the surface of the photoresist mask are connected, which inhibits removal of the photoresist mask. When the insulating layer 30 is formed with the collapsing photoresist mask, the insulating layer 30 may not be formed sufficiently around the MR element 50. In this case, when the photoresist mask is removed, the MR element 50 may be damaged by a stripping solution.

To address these, in the example embodiment, as described above, the MR element 50 and the upper electrode 42 are formed using the inorganic material layer 80. Consequently, according to the example embodiment, the above-described problem due to the photoresist mask can be avoided.

Next, other effects of the magnetic sensor 1 according to the example embodiment will be described. The thickness of the first part 60 of the protective layer 70 may be within a range of 40 to 100% of the thickness of the free layer 53 of the MR element 50. In this case, the damage caused to the free layer 53 in the step of etching the inorganic material layer 80 can be reduced.

Alternatively, the thickness of the first part 60 of the protective layer 70 may be within a range of 20 to 40% of the thickness of the free layer 53 of the MR element 50. In this case, the thickness of the overall magnetic sensor 1 can be reduced.

### Modification Example

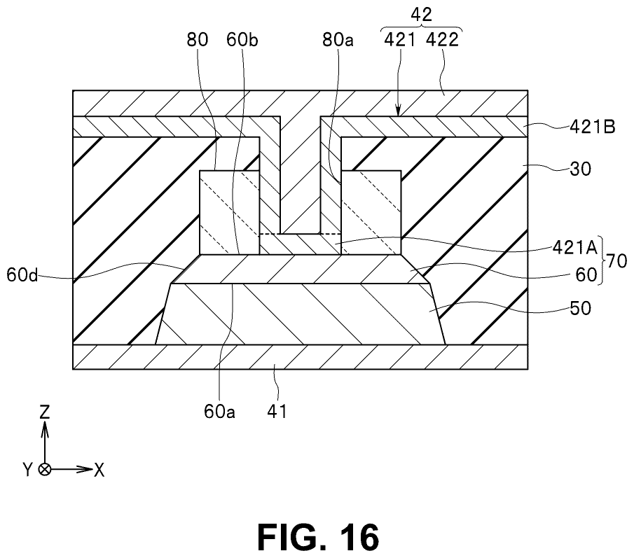

Next, with reference to FIG. 16, a modification example of the example embodiment will be described. FIG. 16 is a cross-sectional view showing a part of the magnetic sensor 1 of a modification example. In the modification example, the angle formed by the side surface 60d of the first part 60 of the protective layer 70 relative to the direction parallel to the Z direction is larger than the angle formed by the side surface of the MR element 50 relative to the direction parallel to the Z direction.

### Second Example Embodiment

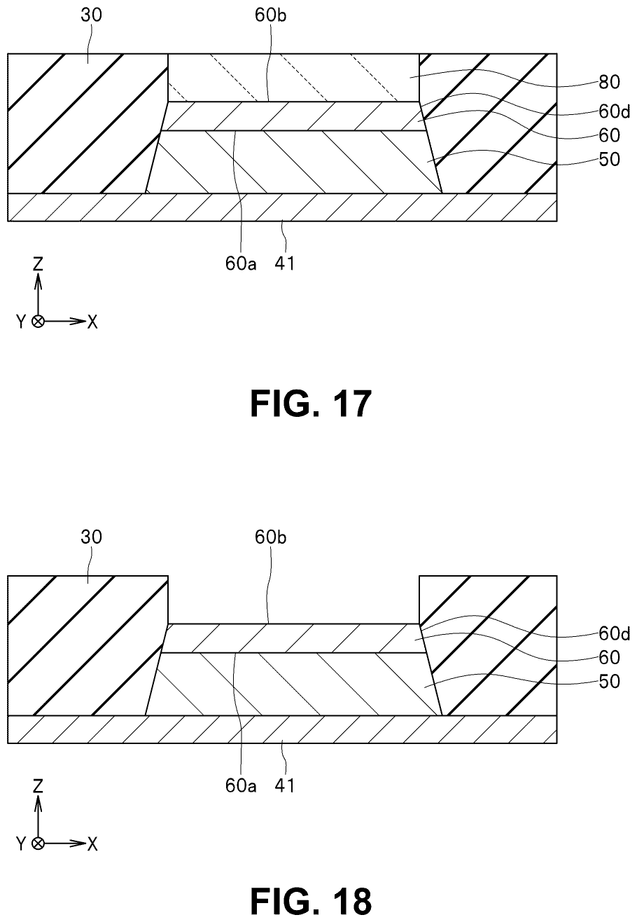

Next, a second example embodiment of the disclosure will be described. First, with reference to FIGS. 17 to 19, a manufacturing method for the magnetic sensor 1 according to the example embodiment will be described. FIGS. 17 to 19 show cross-sections of a stacked body in a manufacturing process for the magnetic sensor 1.

The manufacturing method for the magnetic sensor 1 according to the example embodiment is the same as that of the first example embodiment until the step of forming the insulating layer 30. FIG. 17 shows the next step. In this step, the insulating layer 30 is polished using CMP, for example, until the inorganic material layer 80 is exposed.

FIG. 18 shows the next step. In this step, the inorganic material layer 80 is removed. When the inorganic material layer 80 is formed of carbon, the inorganic material layer 80 is removed using ashing with use of an ashing gas containing O₂, for example. In the example embodiment, in particular, the inorganic material layer 80 is entirely or substantially entirely removed. When the inorganic material layer 80 is removed, a contact hole for connecting the MR element 50 to the upper electrode 42 is formed in the insulating layer 30. In this case, all of the inorganic material layer 80 may be removed from the second surface 60b of the first part 60. In other words, the second surface 60b of the first part 60 may be entirely exposed.

Note that, in the step of etching the inorganic material layer 80, a part of the first part 60 may be etched together with the inorganic material layer 80. When the first part 60 is etched, a recess, which is recessed from the second surface 60b toward the first surface 60a and has such a depth as to not reach the first surface 60a, may be formed in the first part 60.

When the inorganic material layer 80 is removed using ashing with use of an ashing gas containing O₂ as described above, an oxide film is formed on the second surface 60b of the first part 60. Thus, in this case, the oxide film is preferably removed using ion beam etching or reverse sputtering, for example, after the inorganic material layer 80 is removed.

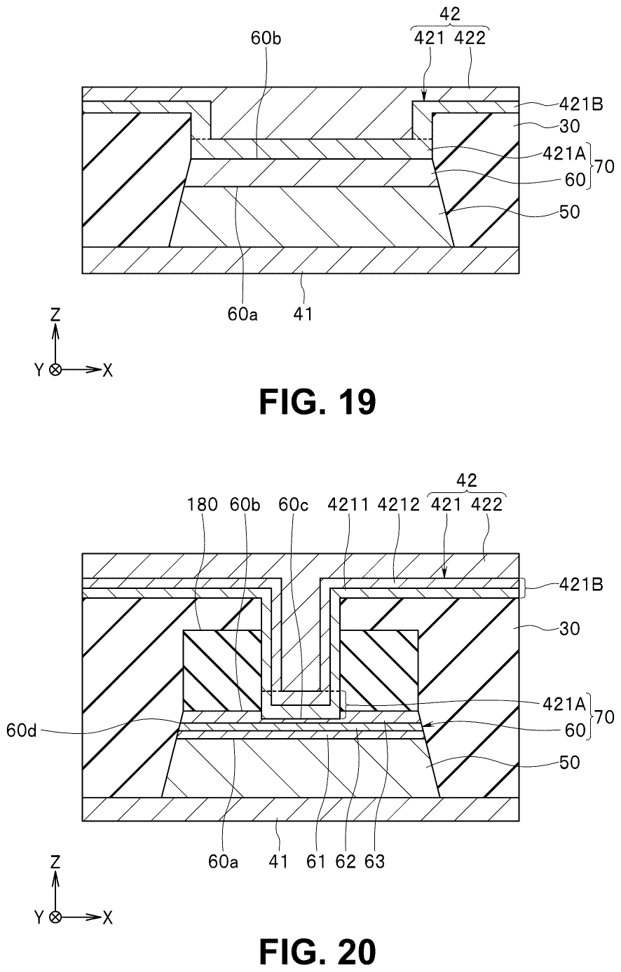

FIG. 19 shows the next step. In this step, the underlayer 421 is formed along the second surface 60b of the first part 60 and the surface of the insulating layer 30. Next, the conductive layer 422 is formed on the underlayer 421. The following steps are the same as those of the first example embodiment.

Next, with reference to FIG. 19, differences of the configuration of the magnetic sensor 1 according to the example embodiment from that of the first example embodiment will be described. In the example embodiment, the outer edge 421Ae of the second part 421A matches or substantially matches the outer edge of the second surface 60b of the first part 60 when viewed in the Z direction. The outer edge 421Ae of the second part 421A may be located on the inner side of the outer edge of the first surface 60a of the first part 60 when viewed in the Z direction.

In the example embodiment, the planar shape of a part of the upper electrode 42 lying inside the contact hole of the insulating layer 30 is the same as or substantially the same as the planar shape of the first part 60 of the protective layer 70. Consequently, according to the example embodiment, the contact area between the first part 60 and the upper electrode 42 (second part 421A) can be increased. As a result, according to the example embodiment, resistance of the overall magnetic sensor 1 can be reduced.

The configuration, operation, and effects of the example embodiment are otherwise the same as those of the first example embodiment.

### Third Example Embodiment

Next, with reference to FIG. 20, a third example embodiment of the disclosure will be described. FIG. 20 is an enlarged cross-sectional view showing a part of the magnetic sensor 1 according to the example embodiment. The configuration of the magnetic sensor 1 according to the example embodiment is different from that of the first example embodiment in the following. In the example embodiment, an inorganic material layer 180 is provided instead of the inorganic material layer 80 in the first example embodiment. The shape and the layout of the inorganic material layer 180 are the same as the shape and the layout of the inorganic material layer 80. The inorganic material layer 180 is formed of Al₂O₃, for example.

Note that, when the inorganic material layer 180 is formed of Al₂O₃, the first part 60 of the protective layer 70 preferably includes an Ni-based non-magnetic alloy such as NiCr or a metal film formed of Ru. The Ni-based non-magnetic alloy or the metal film formed of Ru functions as an etching stopper in the step of etching the inorganic material layer 180. In the example shown in FIG. 20, the first part 60 includes a first layer 61, a second layer 62, and a third layer 63 stacked on the MR element 50 in the mentioned order. The inorganic material layer 180 is disposed on the third layer 63. In the example shown in FIG. 20, the third layer 63 may be a metal film formed of NiCr.

In the example shown in FIG. 20, the underlayer 421 includes a first layer 4211 and a second layer 4212 stacked on the first layer 4211. In this case, the second layer 62 and the second layer 4212 may each be a first metal film formed of the first metal material. The first layer 61 and the first layer 4211 may be formed of the same metal material, or may be formed of metal materials different from each other. In one example, the first layer 61 is a metal film formed of Ru, the second layer 62 is a metal film formed of Ta, the third layer 63 is a metal film formed of NiCr, the first layer 4211 is a metal film formed of Ti, and the second layer 4212 is a metal film formed of Ta.

The configuration, operation, and effects of the example embodiment are otherwise the same as those of the first example embodiment.

### Fourth Example Embodiment

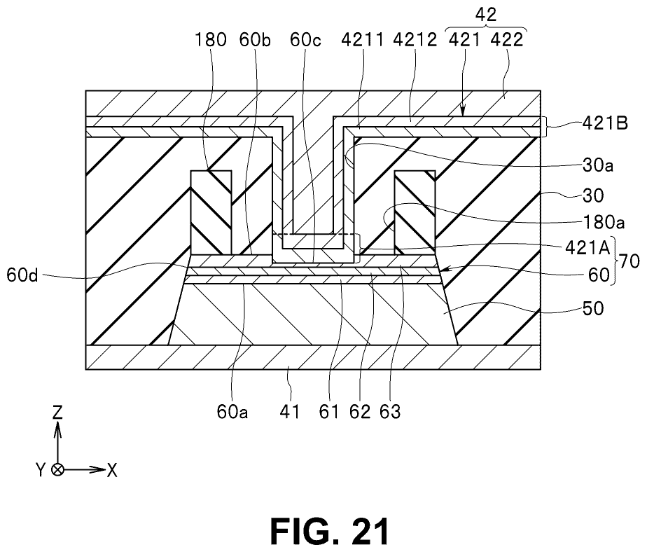

Next, with reference to FIG. 21, a fourth example embodiment of the disclosure will be described. FIG. 21 is an enlarged cross-sectional view showing a part of the magnetic sensor 1 according to the example embodiment. The configuration of the magnetic sensor 1 according to the example embodiment is different from that of the third example embodiment in the following. In the example embodiment, the inorganic material layer 180 includes an opening 180a exposing a part of the second surface 60b of the first part 60 of the protective layer 70. The size of the opening 180a in cross-section of the inorganic material layer 180 parallel to the XY plane may be constant regardless of the distance from the second surface 60b, or may increase as it is more distant from the second surface 60b.

In the example embodiment, in particular, the planar shape of the opening 180a of the inorganic material layer 180 is larger than the planar shape of the second part 421A of the protective layer 70. The insulating layer 30 is interposed between the wall surface of the opening 180a of the inorganic material layer 180 and the second part 421A of the protective layer 70 and between the wall surface of the opening 180a of the inorganic material layer 180 and the part 421B of the underlayer 421.

The insulating layer 30 includes an opening 30a exposing a part of the second surface 60b of the first part 60 of the protective layer 70. The size of the opening 30a in cross-section of the insulating layer 30 parallel to the XY plane may be constant regardless of the distance from the second surface 60b, or may increase as it is more distant from the second surface 60b.

The underlayer 421 including the second part 421A is disposed along the wall surface of the opening 30a of the insulating layer 30 and a part of the second surface 60b.

The outer diameter of the planar shape of the recess 60c of the first part 60 is smaller than the inner diameter of the planar shape of the opening 180a of the inorganic material layer 180, and is the same as or substantially the same as the outer diameter of the planar shape of the opening 30a of the insulating layer 30.

The configuration, operation, and effects of the example embodiment are otherwise the same as those of the third example embodiment.

Note that the disclosure is not limited to the foregoing example embodiments, and various modifications may be made thereto. For example, the shape of the side surface of the MR element 50 and the shape of the side surface 60d of the first part 60 are not limited to the examples described in each example embodiment. For example, the side surface of the MR element 50 may include a curved surface portion. Similarly, the side surface 60d of the first part 60 may include a curved surface portion.

As described above, a magnetic sensor according to one embodiment of the disclosure includes: a magnetoresistive element including a magnetization pinned layer having magnetization with a fixed direction, a free layer having magnetization variable according to a magnetic field to be applied, and a gap layer disposed between the magnetization pinned layer and the free layer; a protective layer disposed above the magnetoresistive element; and a conductive layer electrically connected to the magnetoresistive element. The protective layer includes a first part and a second part, such that the second part is disposed so as to sandwich the first part between the second part and the magnetoresistive element. When viewed in a stacking direction of the magnetization pinned layer, the gap layer, and the free layer, an outer edge of the second part is located on an inner side of the outer edge of the first part. The conductive layer comes in contact with the second part.

The magnetic sensor according to one embodiment of the disclosure may further include an electrode. The electrode may include the conductive layer and an underlayer serving as a seed layer for the conductive layer. The underlayer may include the second part of the protective layer.

In the magnetic sensor according to one embodiment of the disclosure, the first part may include a first metal film formed of a first metal material. The second part may include a second metal film formed of the first metal material. The protective layer may further include a third metal film formed of a second metal material.

In the magnetic sensor according to one embodiment of the disclosure, the first part may include a first surface and a second surface lying at both ends in the stacking direction. The first surface may face the magnetoresistive element. The second surface may face the second part. The first part may further include a recess being recessed from the second surface toward the first surface. At least a part of the second part may be provided within the recess.

The magnetic sensor according to one embodiment of the disclosure may further include an inorganic material layer disposed around the second part on the first part of the protective layer. An outer diameter of a planar shape of the recess when viewed in the stacking direction may be smaller than the outer diameter of the planar shape of the inorganic material layer when viewed in the stacking direction. The outer diameter of the planar shape of the inorganic material layer may be equal to or less than the outer diameter of the planar shape of the magnetoresistive element when viewed in the stacking direction.

The magnetic sensor according to one embodiment of the disclosure may further include an electrode. The electrode may include the conductive layer and an underlayer serving as a seed layer for the conductive layer. The underlayer may include the second part of the protective layer. The electrode may come in contact with the first part of the protective layer. An area of a contact surface between the electrode and the first part of the protective layer may be equal to the area of the planar shape of the recess when viewed in the stacking direction.

In the magnetic sensor according to one embodiment of the disclosure, thickness of the first part of the protective layer in the stacking direction may be within a range of 40 to 100% of the thickness of the free layer in the stacking direction. Thickness of the first part of the protective layer in the stacking direction may be within a range of 20 to 40% of the thickness of the free layer in the stacking direction.

In the magnetic sensor according to one embodiment of the disclosure, the free layer may be configured so that the free layer can have a magnetic vortex structure and a center of the magnetic vortex structure can move according to a target magnetic field.

In the magnetic sensor of the disclosure, when viewed in the stacking direction of the magnetization pinned layer, the gap layer, and the free layer, the outer edge of the second part is located on the inner side of the outer edge of the first part. The conductive layer comes in contact with the second part. Consequently, according to the disclosure, occurrence of a problem due to the conductive layer can be reduced.

It is apparent that the disclosure can be carried out in various forms and modifications in the light of the foregoing descriptions. Accordingly, within the scope of the following claims and equivalents thereof, the disclosure can be carried out in forms other than the foregoing example embodiments.

1. A magnetic sensor comprising:
magnetoresistive element including a magnetization pinned layer having magnetization with a fixed direction, a free layer having magnetization variable according to a magnetic field to be applied, and a gap layer disposed between the magnetization pinned layer and the free layer;
magnetoresistive element; and
magnetoresistive element, wherein
, such that the second part is disposed so as to sandwich the first part between the second part and the magnetoresistive element,

2. The magnetic sensor according to claim 1, further comprising
seed layer for the conductive layer, and

3. The magnetic sensor according to claim 1, wherein

4. The magnetic sensor according to claim 3, wherein

5. The magnetic sensor according to claim 1, wherein
the first part includes a first surface and a second surface lying at both ends in the stacking direction,
magnetoresistive element,

6. The magnetic sensor according to claim 5, further comprising

7. The magnetic sensor according to claim 6, wherein

8. The magnetic sensor according to claim 7, wherein
magnetoresistive element when viewed in the stacking direction.

9. The magnetic sensor according to claim 5, further comprising
seed layer for the conductive layer, and

10. The magnetic sensor according to claim 1, wherein

11. The magnetic sensor according to claim 1, wherein

12. The magnetic sensor according to claim 1, wherein
